(19) United States
(12) Patent Application Publication
(10) Pub. No.: US 2010/0219535 A1
(43) Pub. Date: Sep. 2, 2010

(54) METHOD FOR PRODUCING A SEMICONDUCTOR COMPONENT

(76) Inventors: Martin KUTZER, Penig (DE); Bernd Bitnar, Freiberg (DE); Andreas Krause, Dresden (DE); Michael Heemeier, Dresden (DE); Kristian Schlegel, Zwickau (DE); Torsten Weber, Dresden (DE); Holger Neuhaus, Freiberg (DE); Alexander Fülle, Kirchberg (DE); Eric Schneiderlöchner, Hillsboro, OR (US)

Correspondence Address: MCGLEW & TUTTLE, PC, P.O. BOX 9227, SCARBOROUGH STATION, SCARBOROUGH, NY, 10510-9227, US

(21) Appl. No.: 12/714,461

(22) Filed: Feb. 27, 2010

(30) Foreign Application Priority Data
Feb. 27, 2009 (DE) 10 2009 010 816.5

(51) Int. Cl. H01L 23/488; H01L 21/768

(52) U.S. Cl. 257/773; 438/612; 257/E21.59; 257/E23.023

(57) ABSTRACT

A method for producing a semiconductor component with an easily solderable contact structure comprising the provision of a semiconductor substrate of a planar design with a first side, a second side, a surface normal standing vertically thereon, a dielectric passivation layer arranged on at least one of the sides and a first contact layer arranged on passivation layer, the application, at least in some areas, of at least one second contact layer onto the first contact layer, the at least one second contact layer comprising at least a partial layer made of an easily solderable metal, especially of nickel and/or silver and/or tin and/or a compound thereof, and the making of an electrically conductive contact between the second contact layer and the semiconductor substrate.

### FIELD OF THE INVENTION

The invention relates to a method for producing a semiconductor component. The invention also relates to a semiconductor component with a solderable contact structure.

### BACKGROUND OF THE INVENTION

From DE 100 46 170 A1 there is known a solar cell with laser-fired contacts (LFC solar cell). Said solar cell exhibits on its surface a metal layer of several micrometers in thickness made of aluminium, which layer is locally connected in an electrically conductive way with the semiconductor substrate lying underneath. In order to interconnect individual LFC cells into a module, they are typically soldered to each other. However, as is generally known, the soldering of aluminium is problematic and time-consuming

### SUMMARY OF THE INVENTION

The invention is therefore based on the object of creating a method for producing a semiconductor component with a contact structure, which is easily solderable. The invention is also based on the object of creating a semiconductor component with an easily solderable contact structure.

Said objects are achieved by a method for producing a semiconductor component with an easily solderable contact structure comprising the steps of providing a semiconductor substrate of a planar design having a first side, a second side, a surface normal standing vertically thereon, a dielectric passivation layer arranged on at least one of the sides and a first contact layer arranged on the passivation layer, applying, at least in some areas, at least one second contact layer onto the first contact layer, the at least one second contact layer comprising at least a partial layer made of an easily solderable metal, especially of nickel and/or silver and/or tin and/or a compound thereof, and producing an electrically conductive contact between the second contact layer and the semiconductor substrate.

Said object is further achieved by a semiconductor component comprising a semiconductor substrate of a planar design with a first side, a second side and a surface normal standing vertically thereon, a dielectric passivation layer arranged on at least one of the sides, a first contact layer arranged on the passivation layer and at least one second contact layer arranged, at least in some areas, on the first contact layer, wherein the at least one second contact layer is easily solderable.

The core of the invention consists in applying onto a first contact layer at least one further contact layer which is made of an easily solderable metal.

To produce an electrically conductive connection between the easily solderable second contact layer and the semiconductor substrate, there is preferably envisaged a laser process.

The second contact layer can be applied onto the first contact layer so as to cover its entire surface. This way, especially the cross conductivity of the contact layer is increased so that the thickness of the first contact layer can be reduced significantly.

However, it is equally possible to apply the second contact layer in an interrupted pattern, i.e. in sub-areas separated from each other, onto the first contact layer. This has the advantage that layer stresses in the layer stack are reduced, and bending of the substrate can thus be counteracted.

For the application of the second contact layer, a vacuum method, especially a vapour deposition and/or sputtering method, is preferably envisaged. Preferably, a method corresponding to that for the application of the first contact layer is envisaged for the application of the second contact layer. What is especially advantageous here is that both the application of the first and the second contact layer can be carried out in the same vacuum chamber. As a result, on the one hand, additional process time can be avoided by saving an additional pump-down step, on the other hand, a disadvantageous, spontaneous oxidation of the first contact layer is thus effectively avoided because it does not come into contact with atmospheric oxygen.

The second contact layer can also be applied onto the first contact layer in the form of a foil. This is especially easy to perform. The foil preferably exhibits an adhesive layer, especially made of a particularly conductive adhesive. This way an especially good electrical connection of the foil to the first contact layer is produced.

The foil comprises a layer made of a metal or a metal alloy. Foils with a bimetal layer have proven especially useful.

The semiconductor component according to the invention can be produced in an especially economic way and owing to the characteristics of the second contact structure it is connectable in a solar module in an especially easy way.

Further advantages and details of the invention result from the description of a plurality of embodiments based on the drawings.

### BRIEF DESCRIPTION OF THE DRAWINGS

FIG. 1 a schematic representation of a cross-section through a semi-conductor component according to a first embodiment of the invention,

FIG. 2 a top view onto a semiconductor component according to a second embodiment of the invention and

FIG. 3 a top view onto a semiconductor component according to a further embodiment of the invention.

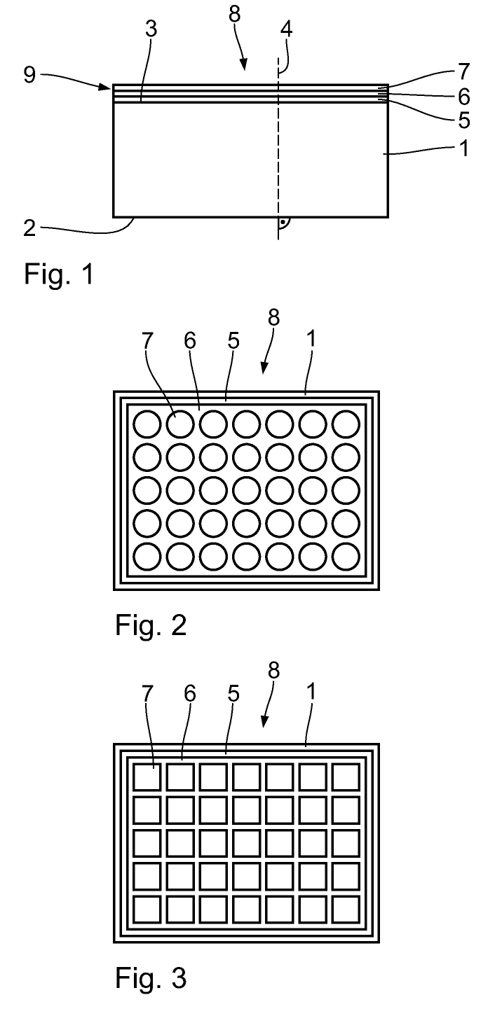

### DESCRIPTION OF THE PREFERRED EMBODIMENTS

In the following there is described a method, according to the present invention for producing a semiconductor component 8 with an easily solderable contact structure. In this context, “easily solderable” means that soldering is possible by means of a soft soldering method. First, there is provided a semiconductor substrate 1 of a planar design with a first side 2, a second side 3 lying opposite thereto, and a surface normal 4 standing vertically thereon. The second side 3 is especially the later rear side, i.e. the side forming the side facing away from the sun during solar cell operation.

Especially a silicon substrate serves as a semiconductor substrate 1. However, another semiconductor substrate may also serve as a semiconductor substrate 1.

On the second side 3 there is arranged an electric passivation layer 5. The passivation layer 5 is made of a dielectric, for example silicon dioxide (SiO₂) or silicon nitride. The passivation layer 5 has a thickness in the direction of the surface normal 4 in a range of 80-150 nm, especially 100 nm

On the passivation layer 5 there is arranged a first contact layer 6. The first contact layer 6 is preferably made of aluminium. It serves as a reflection layer and as a conductor layer, which effects a cross conductivity perpendicular to the surface normal 4. For the application of the first contact layer, a vacuum method, especially a vapour deposition method or a sputtering method is envisaged. Here, the application of the first contact layer 6 occurs in a vacuum chamber. The application occurs especially under the exclusion of oxygen.

Compared with the usual semiconductor components the thickness of the first contact layer 6 is reduced in the direction of the surface normal 4. It is no more than 3 μm, especially no more than 1 μm, especially no more than 0.5 μm. This way both the material and the process time needed for the application of the first contact layer 6 are reduced.

In the following, at least one second contact layer 7 is applied, at least in some areas, onto the semiconductor substrate 1 with the passivation layer 5 and the first contact layer 6. The second contact layer 7 is made of an easily solderable metal, especially of nickel and/or silver and/or tin and/or a compound thereof. For details, reference is made to DE 10 2008 062 591.

The second contact layer 7 is thermally stable up to a temperature of at least 300° C., especially at least 400° C., i.e. there is no mixing of the contact layers 6, 7. Together, the contact layers 6, 7 form a contact structure 9.

For the application of the second contact layer 7 there is again envisaged a vacuum method, especially a vapour deposition and/or a sputtering method. Preferably, the application of the second contact layer 7 occurs in the same vacuum chamber as the application of the first contact layer 6. In this case, the vacuum chamber can advantageously remain evacuated between the application of the first and the second contact layer 6, 7. This avoids an additional pump-down step. Consequently, additional process time is saved. Moreover, a disadvantageous, spontaneous oxidation of the first contact layer 6 is avoided because it does not come into contact with oxygen prior to the application of the second contact layer 7.

The second contact layer 7 is in electrical contact with the first contact layer 6. It thus contributes to the cross conductivity of the latter. According to the first embodiment, the second contact layer 7 is applied onto the first contact layer 6 so as to cover the entire surface.

After the application of the second contact layer 7, an electrically conductive contact is made between the second contact layer 7 and the semiconductor substrate 1. For this, a laser method is envisaged according to the present invention. By means of the laser method the second contact layer 7 is locally fired through passivation layer 5 and in this way an electrical contact is made between the contact layers 6, 7 and the semiconductor substrate 1. Here, the second contact layer 7 can locally form an alloy with the first contact layer 6 and/or the semiconductor substrate.

After the laser process producing the electrically conductive contact between the contact layers 6, 7 and the semiconductor substrate 1, there may be envisaged a tempering step to reduce the damage to the surface of the semiconductor component 8 induced by the laser.

During said tempering step the semiconductor component 8 with the contact layers 6, 7 is heated to a temperature of at least 300° C., especially of about 400° C. or especially of about 500° C. Since the contact layers 6, 7 are thermally stable up to this temperature, they are not damaged thereby.

In another embodiment not shown, the second contact layer 7 has a multi-layer design. It may be especially advantageous to first apply a diffusion barrier layer, especially made of titanium or a titanium compound, onto the first contact layer 6. Said diffusion barrier layer prevents a diffusion of aluminium e.g. into silver. This way, the stability of the contact layers 6, 7 during tempering processes is ensured.

According to another embodiment of the invention, the contact layers 6, 7, especially the second contact layer 7, are precipitated galvanically or chemically, i.e. without current. In the case of a galvanic precipitation of the second contact layer 7 on an aluminium layer, the non-electron-conducting aluminium oxide layer (Al₂O₃ layer) on the surface of the first contact layer 6 must first be removed. To this end, alternating etching with sodium hydroxide (NaOH) and nitric acid (HNO₃) is envisaged. This is followed by treatment with a zincate pickle. During this, there is formed through the exchange of aluminium and zinc ions a superficial zinc layer on which further metal layers may be electrochemically precipitated. It is also possible and in accordance with the present invention to limit the described pre-treatment by means of HNO₃ and NaOH exclusively to the area onto which busbars are to be soldered later. Applying the chemicals locally by pad printing, for example, would lend itself to this. During the subsequent electrochemical coating with e.g. nickel, there are then applied for the duration of the coating, or limited to the first few seconds of the coating, very high current densities of up to 100 A/dm², especially 30 A/dm²-50 A/dm², especially 40 A/dm². This leads to a massive hydrogen development, which causes a breaking through the remaining oxide layer and thus local nickel precipitation.

According to another embodiment it is envisaged to design the second contact layer 7 as a foil. The foil comprises a metal layer made of a metal or a metal alloy. The metal layer preferably comprises a bimetal. Thanks to the conductivity of the foil, a good cross conductivity is achieved. The thickness of the first contact layer 6 in the direction of the surface normal 4 can thus be significantly reduced as for the first embodiment of the invention.

The foil is preferably coated at least on one side, preferably on both sides.

The foil preferably exhibits an adhesive layer. By means of the adhesive layer the foil can be arranged and fastened in a particularly easy way on the first contact layer 6. An electrically conductive adhesive is preferably used here in order to improve the electrical connection of the foil to the first contact layer 6. The electrical contact between the foil, the first contact layer 6 and the semiconductor substrate 1 is made by a subsequent laser process.

According to another embodiment of the invention, which is shown in FIGS. 2 and 3, the second contact layer 7 is applied in an interrupted pattern, i.e. in sub-areas separated from each other, onto the first contact layer 6. It is thus not designed to cover the entire surface. This has the advantage that layer stresses in the layer stack are reduced, through which bending of the semiconductor substrate 1 may can be counteracted. Application in an interrupted pattern can e.g. be carried out through a mask.

What is claimed is:

1. A method for producing a semiconductor component (8) with an easily solderable contact structure (9) comprising the following steps:
Providing a semiconductor substrate (1) of a planar design having
a first side (2),
a second side (3),
a surface normal (4) standing vertically thereon,
a dielectric passivation layer (5) arranged on at least one of the sides (2, 3) and
a first contact layer (6) arranged on the passivation layer (5),
applying, at least in some areas, at least one second contact layer (7) onto the first contact layer (6),
the at least one second contact layer (7) comprising at least a partial layer made of an easily solderable metal, and
producing an electrically conductive contact between the second contact layer (7) and the semiconductor substrate (1).

2. A method for producing a semiconductor component (8) with an easily solderable contact structure (9) according to claim 1, wherein the at least one partial layer of the at least one second contact layer (7) is made of at least one of nickel, silver, tin and a compound thereof.

3. A method according to claim 1, wherein a laser method is envisaged for producing the electrically conductive contact between the second contact layer (7) and the semiconductor substrate (1).

4. A method according to claim 1, wherein the at least one second contact layer (7) is applied onto the first contact layer (1) so as to cover its entire surface.

5. A method according to claim 1, wherein first a diffusion barrier layer is applied onto the first contact layer (6).

6. A method according to claim 1, wherein the diffusion barrier layer is made of one of the group of
titanium
titanium compound.

7. A method according to claim 1, wherein the at least one second contact layer (7) is applied in an interrupted pattern onto the first contact layer (6).

8. A method according to claim 1, wherein the at least one second contact layer (7) is applied by means of a vacuum method, the application taking place in a vacuum chamber.

9. A method according to claim 8, wherein the vacuum method is at least one of a vapour deposition and a sputtering method.

10. A method according to claim 1, wherein both the first contact layer (6) and the at least one second contact layer (7) are applied bay means of a vacuum method, the application taking place in a vacuum chamber.

11. A method according to claim 7, wherein the application of at least one second contact layer (7) takes place in the same vacuum chamber as the application of the first contact layer (6), the vacuum chamber remaining evacuated between the application of the first contact layer (6) and the at least one second contact layer (7).

12. A method according to claim 1, wherein the at least one second contact layer (7) is applied by means of at least one of a galvanic and a current-free chemical method.

13. A method according to claim 1, wherein the second contact layer (7) comprises a foil.

14. A Method according to claim 13, wherein the foil is coated on at least one side.

15. A method according to claim 10, wherein at least one of the foil and its coating are made of a metal.

16. A method according to claim 15, wherein at least one of the foil and its coating are made of one of the group of
a bimetal
a metal alloy.

17. A method according to claim 15, wherein at least one of the foil and its coating are made of at least one of nickel and silver and tin and a compound thereof.

18. A semiconductor component (8) comprising
a) a semiconductor substrate (1) of a planar design with
i. a first side (2),
ii. a second side (3) and
iii. a surface normal (4) standing vertically thereon,
b) a dielectric passivation layer (5) arranged on at least one of the sides (2, 3),
c) a first contact layer (6) arranged on the passivation layer (5) and
d) at least one second contact layer (7) arranged, at least in some areas, on the first contact layer (6),
e) wherein the at least one second contact layer (7) is easily solderable.

19. A semiconductor component (8) according to claim 18, wherein the at least one second contact layer (7) is thermally stable up to a temperature of at least 300° C.

20. A semiconductor component (8) according to claim 18, wherein the at least one second contact layer (7) is thermally stable up to a temperature of at least 400° C.
